(19) United States
(12) Patent Application Publication
(10) Pub. No.: US 2008/0241432 A1
(43) Pub. Date: Oct. 2, 2008

(54) Pocket wallpaper border with printed "Blank Areas or Regions"

(76) Inventor: Charlotte Arce, Schiller Park, IL (US)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/773,389

(22) Filed: Jul. 3, 2007

Related U.S. Application Data
(60) Provisional application No. 60/901,127, filed on Feb. 13, 2007.
(60) Provisional application No. 60/920,793, filed on Mar. 30, 2007.

(51) Int. Cl. B44C 3/12; G03F 1/14

(52) U.S. Cl. 428/14; 156/63

(57) ABSTRACT

A wallpaper border display apparatus having a wallpaper border, a blank region on the wallpaper border which is separately identifiable and distinguishable from the wallpaper border, and a receptacle attached to the blank region, the receptacle configured to receive therein an item and having a surface through which said item can be viewed.

### BACKGROUND OF THE INVENTION

The present invention generally relates to the field of wallpaper. In particular, the invention relates to methods and devices for personalizing wallpaper borders.

Wallpaper borders and memorabilia are popular means to decorate rooms. A wallpaper border is a decorative strip that features a pre-designed image or pattern. The wallpaper border is applied to a surface, such as a wall, to create an aesthetically pleasing appearance. Wallpaper borders are available in a wide variety of designs; however, the design options are limited to pre-designed images and patterns.

Memorabilia, such as photographs, post cards and trading cards or the like are commonly stored or displayed in scrapbooks, photo albums and picture frames. Displaying memorabilia on walls presents the problem of limited wall space and wall clutter.

Attempts to combine images with displays have been made in the prior art. For example, in U.S. Pat. No. 6,124,953 there exists a wallpaper construction for holographic images. The wallpaper construction comprises multiple sheets to achieve a display device for holographic images. In U.S. patent application Ser. No. 11/063,800, photographic display units are joined by a connecting mechanism to form a decorative border. In U.S. patent application Ser. No. 11/253,481, there exists a wallpaper picture frame made of two sheets with a cut out window in one of the sheets to display pictures.

The prior art fails to provide a simple wall display means for pictures and memorabilia. Thus, there is a need for a wallpaper border that allows a user to personalize the wallpaper border in an easy, convenient simple and inexpensive manner.

### SUMMARY OF THE INVENTION

The present invention provides an improved wallpaper border that allows an individual to personalize the wallpaper boarder with relative ease.

To that end, in an embodiment, the present invention provides a wallpaper border display apparatus in which memorabilia can be attached to the wallpaper border on a printed blank region.

In an embodiment, the invention provides a means for attaching the memorabilia to a printed blank region such that the memorabilia can be easily inserted, displayed, removed and/or replaced.

In an embodiment, the invention provides a pocket or sleeve as a means for attaching memorabilia to the blank region.

In an embodiment, the invention provides an adhesive backed sheet as a means for attaching memorabilia to the blank region.

In an embodiment, the invention provides blank regions that are varied in shape and size.

In an embodiment, the invention provides a wallpaper border that includes a decorative design.

In an embodiment, the invention provides blank regions that have printed instructions for use.

In an embodiment, the invention provides blank regions that have printed advertisements.

An aspect of the invention is to provide a method for personalizing wallpaper border.

These and other features and aspects of the invention are set forth in detail below with reference to the accompanying drawings in the following detailed description of the presently preferred embodiments.

### BRIEF DESCRIPTION OF THE DRAWINGS

FIG. 1 illustrates a two dimensional front view of a wallpaper border.

FIG. 2 illustrates a two dimensional front of a pocket or sleeve.

FIG. 3 illustrates a two dimensional front a pocket or sleeve.

FIG. 4 illustrates two-dimensional front view of a wallpaper border with blank regions varying in shape.

FIG. 5 illustrates a flow diagram of a method embodying principles of the invention.

### DETAILED DESCRIPTION OF THE PRESENTLY PREFERRED EMBODIMENTS

Embodiments of the present invention will be described in detail below with reference to accompanying drawings.

Wallpaper borders are generally well known and commercially available. These are strips of wallpaper generally applied along an edge, such as a wall edge or parallel to a chair rail. The effect is to create a distinctly different portion of space or area along the edge where the wallpaper border is applied.

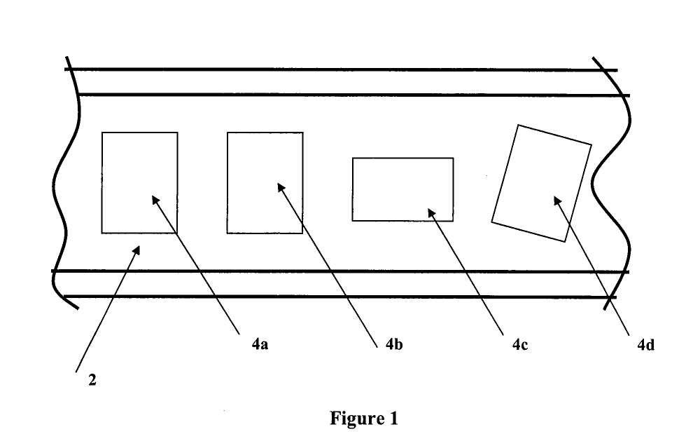

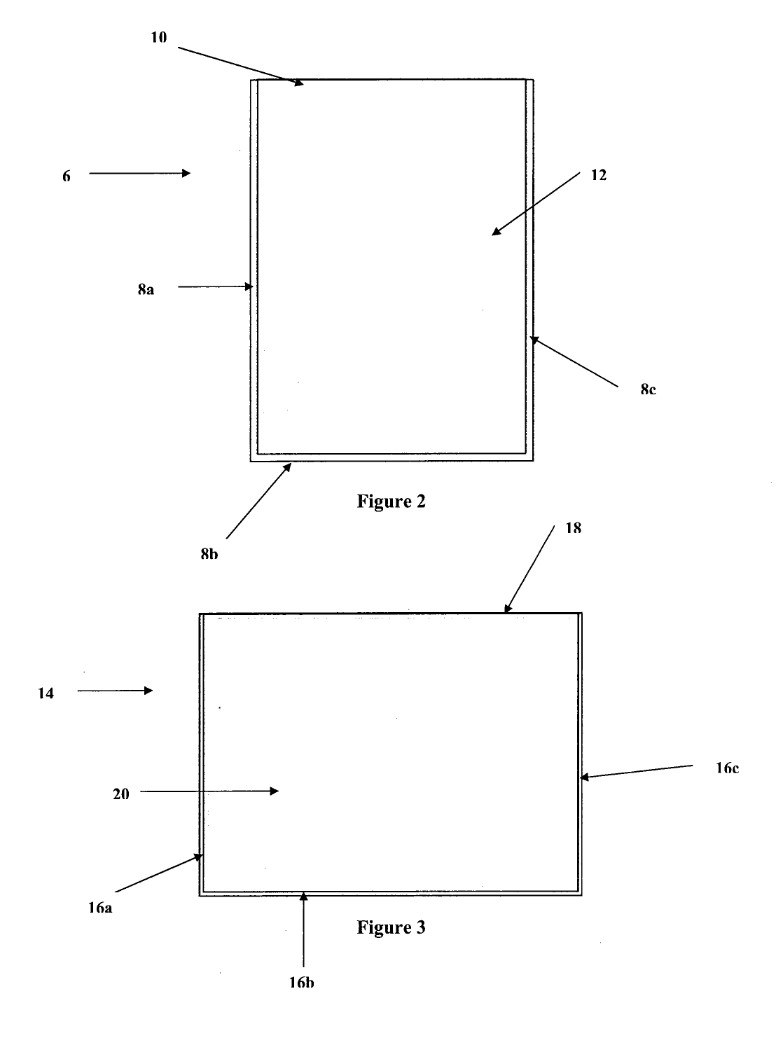

In FIG. 1, there is illustrated a portion of wallpaper border comprising a portion of a sheet of wallpaper border 2 with a blank regions 4a-4d. The blank regions 4a-4d are regions that are separately identifiable or distinguishable from the wallpaper border 2 and are designated for a pocket or sleeve FIGS. 2 and 3. The blank regions 4a-4d may be printed on the surface of the wallpaper border 2 to distinguish the blank regions 4a-4d from the wallpaper border. The blank regions 4a-4d can appear as repeating pattern or as random pattern along the wallpaper border.

The blank regions 4a-4d can be the same shape or different shapes. For example, the blank region 4a has a vertical dimension that is greater than its' horizontal dimension. Additionally, blank region 4c has a horizontal dimension which is greater than its' vertical dimension.

The orientation of the blank regions 4a-4d on the wallpaper border can vary in direction. For example, as seen in blank region 4d, the orientation of the blank region can be tilted at any particular angle with respect to another blank region such as 4a or 4c. Furthermore, the blank region 4c can be horizontally placed on the wallpaper border. The blank region 4a can also be vertically placed on the wallpaper border.

In FIG. 2, there is illustrated a pocket or sleeve 6. The pocket or sleeve 6 has three sealed or closed edges 8a-8c. The edges 8a-8c of the pocket or sleeve can be sealed by any suitable well-known means used for sealing purposes. Preferably, the edges 8a-8c are heat sealed or fused by radio frequency welding, ultra sonic welding, impulse heating, heat stake processes or the like. An opening 10 is located at the top of the pocket or sleeve 6. The opening 10 is the point through which memorabilia is inserted into the pocket or sleeve 6 or removed from the pocket or sleeve 6. The pocket or sleeve 6 has a transparent top sheet 12 through which the memorabilia is protected, viewed and displayed.

The pocket or sleeve has an adhesive backing (not shown) which is used as a means to attach the pocket or sleeve to the blank regions 4a-4d of the wallpaper border 2. The adhesive backing is a color that is not visually distracting from the wallpaper border 2 such as white or a color matching the wallpaper border 2. The adhesive backing can be a pressure sensitive adhesive backing or a contact adhesive backing effective to adhere the pocket or sleeve FIGS. 2 and 3 to the wallpaper border 2. Preferably, the adhesive backing is in the form of a tape, film, coating or the like.

In FIG. 3, another pocket or sleeve 14 is shown. The pocket or sleeve 14 has three sealed or closed edges 16a-16c. An opening 7 is located at the top of the pocket or sleeve. The pocket or sleeve has a transparent top sheet 8 through which memorabilia is protected, viewed and displayed. The pocket or sleeve has an adhesive backing (not shown) which is used as a means to attach the pocket or sleeve to the blank regions 4a-4d of the wallpaper border 2.

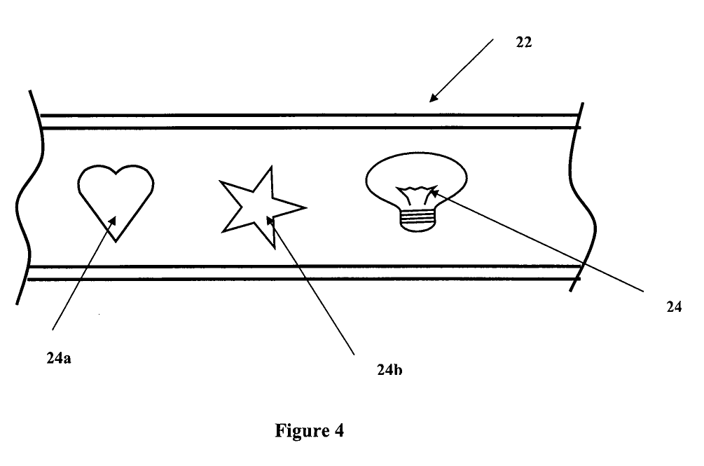

In another embodiment shown in FIG. 4 the blank regions, vary in shape 24a-24c. The shape of the blank region may be an abstract shape 24c or any known shape such as a heart 24a, star 24b, circle, triangle, animal, plants or any other known shape. The blank regions 24a-24c are separately identifiable and distinguishable from the wallpaper border 22 and are designated for an adhesive backed sheet (not shown) such as a sticker or the like. The blank regions 24a-24c may be printed on the surface of the wallpaper border 22 to distinguish the blank regions 24a-24c from the wallpaper border.

An adhesive backed sheet (not shown) with an image printed on the surface of the adhesive backed sheet is placed in the blank region of varying shape 24a-24c to create a personalized wallpaper border. The image printed on the surface can be any image including a photographic image. The adhesive backed sheet has an outline corresponding to the blank regions 24a-24c such that the shapes coincide with each other when the adhesive backed sheet is placed on the wallpaper border 22. The adhesive backed sheet has an upper surface on which and image is printed and a lower surface which is a pressure sensitive adhesive, contact adhesive or any other suitable adhesive to adhere the adhesive backed sheet to the wallpaper border 22. The wallpaper border can have blank regions for both pockets or sleeves 6 and 14 and adhesive backed sheets.

The wallpaper border 2 or 22 can have preprinted decorative designs including cartoon characters, sports themes and the like. The preprinted decorative designs can create a theme with the type of memorabilia displayed in the blank regions 4a-4d and 24a-24c.

The blank regions 4a-4d and 24a-24c may have pre-printed instructions for use in the blank region, which are later covered by the pocket or sleeve 6 and 16 or adhesive backed sheet. Alternatively, the blank regions 4a-4d and 24a-24c may have pre-printed advertisements that are later covered by the pocket or sleeve or adhesive backed sheet.

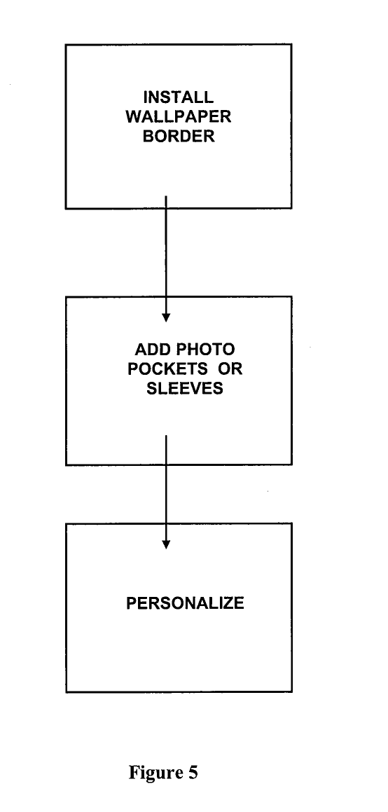

The invention also covers a method shown in FIG. 5 for personalizing the wallpaper border 2 or 22 which includes the steps of installing the wallpaper border 2 or 22 on a surface, attaching the pockets or sleeves 6 and/or 14 to the wallpaper border 2 or 22 and personalizing the wallpaper border by inserting memorabilia into the pocket or sleeve 6 and 14, displaying the memorabilia in the pocket or sleeve 6 and 14 and removing the memorabilia from the pocket or sleeve 6 and 14 to replace with new memorabilia. The method can further include the step of personalizing the wallpaper border 2 or 22 by placing adhesive backed sheets on the wallpaper border 2 or 22 such that the wallpaper border 2 or 22 has both adhesive backed sheets and pockets or sleeves 6 and 14. In other alternatives, the wallpaper border 2 or 22 can be personalized with only adhesive backed sheets, only pockets or sleeves 6 and 14 or any combination of pockets or sleeves 6 and 14 and adhesive backed sheets.

While the invention has been described with reference to the embodiments and the examples, the invention is not limited to the foregoing embodiments and the foregoing examples and various modifications may be made.

What is claimed:

1-19. (canceled)

20. A wallpaper border display apparatus comprising:
a wallpaper border;
a blank region on the wallpaper border which is separately identifiable and distinguishable from the wallpaper border; and
a receptacle attached to the blank region, the receptacle configured to receive therein an item and having a surface through which said item can be viewed.

21. A wallpaper border display apparatus according to claim 20 wherein, the receptacle is a pocket or sleeve having three sealed edges and an opening through which the item is inserted into the pocket or sleeve and through which the item is removed from the pocket or sleeve.

22. A wallpaper border display apparatus according to claim 22 wherein, the pocket or sleeve has an adhesive backing effective to attach the pocket or sleeve to the wallpaper border.

24. A wallpaper border display apparatus according to claim 20 wherein, the blank region is varied in shape and/or size, the placement of the blank region is varied in direction and the blank regions can appear in a repeating pattern or a random pattern.

25. A wallpaper border display apparatus according to claim 20 wherein, the wallpaper border includes a decorative design.

26. A wallpaper border display apparatus according to claim 20 wherein, the blank region includes printed instructions for use.

27. A wallpaper border display apparatus according to claim 20 wherein, the blank region includes printed advertisements.

28. A wallpaper border display apparatus comprising:
a wallpaper border;
a blank region on the wallpaper border which is separately identifiable and distinguishable from the wallpaper border; and
an adhesive backed sheet having an image thereon and attached to the blank region, the adhesive backed sheet configured to coincide with a shape of the blank region.

29. A wallpaper border display apparatus comprising:
a wallpaper border,
a blank region on the wallpaper border, which is separately identifiable and distinguishable from the wallpaper border;
a receptacle attached to the blank region, the receptacle configured to receive therein items and having a surface through which said item can be viewed; and
an adhesive backed sheet having an image thereon and attached to the blank region, the adhesive backed sheet configured to coincide with a shape of the blank region.

30. A method for personalizing a wallpaper border comprising the steps of:
applying a wallpaper border with a blank region which is separately identifiable and distinguishable from the wallpaper border; and
attaching a receptacle to the blank region, the receptacle configured to receive therein an item and having a surface through which said item can be viewed.

31. The method according to claim 27, wherein the method further comprises the step of applying an adhesive backed sheet having an image thereon and configured to coincide with a shape of the blank region.
